(19) United States
(12) Patent Application Publication
(10) Pub. No.: US 2017/0222067 A1
(43) Pub. Date: Aug. 3, 2017

(54) SURFACE PASSIVATION OF HIGH-EFFICIENCY CRYSTALLINE SILICON SOLAR CELLS

(71) Applicant: Solexel, Inc., Milpitas, CA (US)

(72) Inventors: Sean M. Seutter, San Jose, CA (US); Mehrdad M. Moslehi, Los Altos, CA (US)

(21) Appl. No.: 15/490,494

(22) Filed: Apr. 18, 2017

Related U.S. Application Data
(63) Continuation of application No. 14/325,356, filed on Jul. 7, 2014.
Application No. 14/325,356 is a continuation-in-part of application No. 13/092,942, filed on Apr. 23, 2011, now abandoned.
(60) Provisional application No. 61/327,506, filed on Apr. 23, 2010.
(60) Provisional application No. 61/843,429, filed on Jul. 7, 2013.

(51) Int. Cl. H01L 31/0216; H01L 31/18

(52) U.S. Cl. CPC H01L 31/02167; H01L 31/1868; H01L 31/1864

(57) ABSTRACT

Stable surface passivation on a crystalline silicon substrate is provided by forming a more heavily doped region as a front surface field and/or a doped dielectric layer under a passivation layer on the silicon substrate surface. A passivation layer is deposited on the front surface field and/or doped dielectric layer.

### CROSS-REFERENCE TO RELATED APPLICATIONS

This application is a continuation of U.S. patent application Ser. No. 14/325,356, filed Jul. 7, 2014, which in turn is a continuation-in-part of U.S. patent application Ser. No. 13/092,942, filed Apr. 23, 2011, which claims the benefit of U.S. Provisional Patent Application No. 61/327,506, filed Apr. 23, 2010, and U.S. provisional Patent Application No. 61/843,429, filed on Jul. 7, 2013, the entire contents of each of which is hereby incorporated by reference in their entirety.

### FIELD OF THE INVENTION

This disclosure relates in general to the field of photovoltaics and solar cells, and more particularly to surface passivation of silicon solar cells.

### BACKGROUND

The performance of semiconductor crystalline silicon based devices, such as solar cells, depends strongly on minority carrier recombination in the bulk as well as surface regions of the cell itself. Consequently, reducing the surface recombination is of the utmost importance for these devices. Surface recombination effects are becoming progressively more important as silicon semiconductor device dimensions, such as solar cell wafer thickness, are reduced. The surface passivation of silicon using amorphous films based on hydrogenated silicon compounds has been the subject of intense research in recent years, particularly for solar cell applications. Significant reductions in the effective surface recombination velocity (seff) at the silicon interface have been reported when passivated with amorphous silicon, amorphous silicon oxide, amorphous silicon nitride, and amorphous silicon carbide. Studied films include amorphous, hydrogenated silicon nitride (SixNy:Hz), hereafter referred to as SiNx films. These films are typically deposited by plasma-enhanced chemical vapor deposition (PECVD) at low temperature (400° C.) using silane gas and other reactant gases such as ammonia or nitrogen. Current methods have demonstrated that the surface passivation is maximized when silicon-rich SiNx films with refractive index greater than 2.3 were used, but such films also suffer from loss of light trapping efficiency by absorption in the passivation layer.

Historically, front (light receiving) side passivation is reported to be better utilizing thermal oxide which provides relatively low surface recombination velocities, and there have been extensive studies on the impact of silicon nitride deposition conditions and their impact on passivation. With the current efforts on increasing the solar cell efficiency for crystalline silicon based devices through cell structure development, reducing surface recombination velocity is critical. In conventional cell structures with front and back contact or all back contact structures, passivation reducing front surface recombination and good light trapping properties are key requirements for the front side light receiving surface. Often these two key requirements conflict due to the material properties of SiNx layers. Deposition parameters used for the passivation/ARC layer also pose restrictions on the device manufacturing due to requirements such as the use of low temperatures in subsequent processing steps and the restricted window of temperature with which passivation may be achieved.

As applied to thin film structures, low temperature deposition is critical because of the mechanically weak thin substrates that may not be compatible with high temperature processing. However, many current passivation methods, such as the use of thermal oxide and silicon nitride as passivation layers, require high temperature processes to be effective as both a passivation and light trapping layer.

### SUMMARY

Therefore a need has arisen for superior surface passivation methods which provide enhanced optical properties for crystalline silicon substrates and may be processed at low temperatures. In accordance with the disclosed subject matter, passivation methods and structures are provided which substantially eliminate or reduces disadvantage and problems associated with previously developed passivation methods.

According to one aspect of the disclosed subject matter, a passivation structure on a surface of a crystalline silicon substrate a is provided. A doped dielectric layer having a thickness less than approximately ten nanometers is positioned on the surface of a crystalline silicon substrate. And a plasma-deposited hydrogen-containing silicon nitride layer on the doped dielectric layer.

Technical advantages of the disclosed subject matter include low processing temperatures, improved surface passivation, and increased optical properties for silicon substrates.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIG. 1 is a graph comparing surface passivation quality (Seff) with PECVD SiNx film refractive index (RI) on a dual layer stack with wet chemical oxide showing tuning deposition parameters of SiN at 400° C.;

FIG. 2 is a graph showing a passivation quality comparison of 400° C. amorphous Si/SiN and chem-ox/400 C SiN dual layer stack with thermal (high-temp) oxide/SiN stack;

FIG. 3 is a graph showing optical parameters i.e. refractive index(n) and extinction coefficient (k) vs wavelength for dual layer stack vs Single layer SiN showing matched parameters with thin amorphous Si layer;

FIG. 4 is a graph showing passivation performance at 250° C. of dual layer stack (a-Si 10 A and 30 A/SiN and chem-ox/SiN);

FIG. 5 is a graph showing passivation (Seff) vs amorphous Si layer thickness in a-Si/SiN stack with varying processing temperatures;

FIG. 6 is a graph showing passivation (Seff) vs temperature in a-Si/SiN stack with varying processing temperatures;

FIGS. 7A and 7B, 8, and 9 are a high level process flows for low temperature stable silicon surface passivation;

FIG. 10 is a representative process flow for forming a back contact back junction backplane attached solar cell; and

FIG. 11 is a cross-sectional diagram of a representative back contact back junction solar cell.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like numbers being used to refer to like and corresponding parts of the various drawings.

High-quality surface passivation is needed to obtain low surface recombination velocities and high effective minority carrier lifetimes on crystalline silicon substrates for various applications, including solar photovoltaic cells. Historically superior surface passivation techniques have included using a high temperature thermal oxidation process. However, these high temperature processes may be undesirable for the manufacture of thin film solar cells in part due to the mechanically weak nature of thin film silicon substrates. Thus, the present disclosure provides methods for achieving high-quality, reduced recombination passivation on silicon surfaces while maintaining good optical properties (including negligible optical absorption) that are needed for high performance solar cells through low-temperature processes. The processes disclosed herein comprise appropriate surface preparation and cleaning, growth and/or deposition of bi-layer thin films, e.g. hydrogenated silicon nitride on chemical oxide or on amorphous silicon, and final post-annealing. The low-temperature processes disclosed achieve surface recombination velocities that are equivalent to or lower than the results obtained using known high temperature thermal oxidation processes.

The described embodiments provide good surface passivation along with good optical properties for crystalline silicon substrates at lower processing temperatures—preferably at or below 250° C. and as low as 100° C. deposition and post-deposition. Yet another advantage of the disclosed subject matter is to provide processes for highly efficient surface passivation of silicon substrate based solar cells that may be readily incorporated into and used by existing manufacturing processes as well as future technologies that may require use of low temperature processing for surface passivation.

The disclosed subject matter provides a method for obtaining ultra-low surface recombination velocities from highly efficient surface passivation in crystalline (monocrystalline or multicrystalline) thin (1 μm to 150 μm) silicon substrate-based solar cells by utilizing a dual layer passivation scheme which also works as an efficient ARC. The dual layer passivation consists of a first thin layer of wet chemical oxide (such as a SiO2 layer 1-3 nm thick) or a thin hydrogenated (preferably controlled hydrogenation) amorphous silicon layer (such as a-Si layer 1-10 nm thick) followed by depositing an amorphous hydrogenated silicon nitride film (SiNx:H 10-1000 nm) on top of the wet chemical oxide or amorphous silicon film. This deposition is then followed by anneal in N2+H2 ambient (forming gas anneal, FGA) or N2 ambient at temperatures equal to or greater than the deposition temperature to further enhance the surface passivation.

Importantly, the hydrogenated amorphous silicon nitride thin film itself may be a bi-layer or multi-layer. In one embodiment, the hydrogenated amorphous silicon nitride thin film bi-layer may comprise a first layer with a higher index of refraction and higher relative silicon-to-nitrogen ratio and a second layer with a lower index of refraction and a lower silicon-to-nitrogen ratio. Thus the layer with the higher refractive index is positioned closer to the silicon substrate and the layer with the lower refractive index is positioned closer to the silicon substrate.

The two layers described above may be deposited in a single processing step or in sequential processing steps, within the same chamber, or with or without air exposure or a vacuum break. The silicon nitride and amorphous silicon films may be deposited using plasma enhanced chemical vapor deposition (PECVD) with direct or remote plasma of low frequency or high frequency, and using an in-line or batch/cluster tool. Other methods of deposition include low pressure chemical vapor deposition (LPCVD), physical vapor deposition (PVD), atmospheric chemical-vapor deposition (APCVD), plasma sputtering, or ion-beam deposition (IBD).

Surface pre-treatment plays a critical role prior to deposition of the passivation films. In the case of formation of dual layer passivation involving wet chemical oxide, the textured or flat silicon surface needs to be cleaned with solutions involving, but not limited to HF and HCl. Solutions with NH4OH:H2O2 or HCl:H2O2 may also be used. The surface clean thus forms a clean hydrophobic hydrogen-passivated silicon surface. The surface clean step is then followed by an aqueous HNO3 (10-50% dilution) dip at temperatures in the range of 20-80° C. or a DI water with ozone (DIO3) dip or an ozonated DI water+dilute HF mixture dip (thereby hydrogen passivating the surface), which forms a wet chemical oxide layer in the range of 0.3-5 nm thick properly without any contaminants that may degrade the surface quality and hence surface passivation. The thickness of the oxide layer may be adjusted depending on desired properties, thus the disclosed subject matter includes all thicknesses in the disclosed range (such as 0.5-5 nm).

In the case of dual layer passivation involving amorphous silicon thin films, all of the native silicon oxides need to be removed from the surface. Other metallic and organic surface contaminants should also be removed. Thus the substrate is cleaned in dilute HF prior to deposition. The HF clean may be preceded by the surface clean involving solutions HF, HCl and/or NH4OH:H2O2, HCl:H2O2 solutions. After proper surface treatment and cleaning, the deposition of chemical oxide or amorphous silicon and then the silicon nitride is carried out—thereby forming the dual stack bi-layer.

In the case of passivation involving wet chemical oxide and silicon nitride, the cleaned substrate with chemical oxide is introduced into the deposition chamber where silicon nitride 10-200 nm (or as thin as 10-100 nm) thick with refractive index between 1.85-2.3 (or 1.85-2.2 dependent on desired properties) is deposited using plasma enhanced chemical vapor deposition using SiH4 and NH3 at temperatures in the range of 100-500° C., or more particularly in the range of 100-450° C. Other process embodiments may utilize a silicon containing gas such as disilane (Si2H6) or a metal-organic silicon source as an ambient and a nitrogen and hydrogen containing gas such as, NH3, H2, and N2 gas precursors. The thickness of the silicon nitride layer may be adjusted depending on desired properties, thus the disclosed subject matter includes all thicknesses in the disclosed range.

In the case of passivation involving hydrogenated amorphous silicon thin film (for example amorphous silicon a-Si, amorphous silicon containing oxygen and/or carbon a-SiOC, or amorphous silicon containing oxygen and/nitrogen a-SiON), the cleaned substrate having an oxide free surface (prepared by a dilute HF dip, for example) is introduced into the deposition chamber where a thin layer in the range of 1-10 nm thick of amorphous silicon is deposited using plasma enhanced deposition using SiH4, with or without H2 as a precursor, at temperatures in the range of 100-500° C., or more particularly 100-400° C. Other process embodiments may utilize silicon containing gas such as disilane (Si2H6) or an organo-silicon source, and an additional gas such as H2 and N2 gas precursors. The thickness of the silicon thin film may be adjusted depending on desired properties, thus the disclosed subject matter includes all thicknesses in the disclosed range. Further, embodiments of the hydrogenated amorphous silicon thin film include hydrogenated amorphous sub-stoichiometric silicon oxide, hydrogenated amorphous sub-stoichiometric silicon nitride, hydrogenated amorphous sub-stoichiometric silicon oxynitride, and hydrogenated amorphous sub-stoichiometric silicon carbide.

Following the amorphous silicon deposition a plasma enhanced chemical vapor deposition of a silicon nitride film with a thickness in the range of 10-200 nm (or as thin as 10-100 nm) and a refractive index between 1.85-2.3 (or 1.85-2.2 dependent on desired properties) is performed at temperatures in the range of 100-500° C., or more particularly 100-400° C. Process embodiments may utilize a silicon containing gas such as SiH4, disilane (Si2H6), or a metal-organic silicon source as an ambient and a nitrogen and hydrogen containing gas such as, NH3, H2, and N2 gas precursors. The thickness of the silicon nitride layer may be adjusted depending on desired properties, thus the disclosed subject matter includes all thicknesses in the disclosed range.

After deposition of the passivation stack, the substrate is annealed at preferably the same temperature as the temperature of deposition, although the annealing temperature may be higher (for example between 100-500° C., or more particularly 100-450° C.). Further, performing post anneal in a vacuum, in nitrogen or forming gas (N2, H2, NH3, or forming gas ambient such as N2+H2) may improve the passivation. For example, maintaining the anneal temperature between 100-450° C. for about 1-120 minutes helps preserve the optical properties of the passivation layer for its conducive use as an anti-reflective coating (ARC) and improves the surface passivation. However, importantly the process embodiments of the disclosed subject matter may or may not utilize post-deposition annealing in forming gas or nitrogen.

An important aspect of the disclosed subject matter concerns finding the correct process-property relationship for the method of passivation where the key component of passivation, i.e. silicon nitride, has to be optimized for its dual role as passivation dielectric and efficient anti-reflective coating (ARC) providing efficient light trapping (such as by minimizing optical reflection losses). Deposition parameters for the hydrogenated amorphous silicon thin film and the hydrogenated amorphous silicon nitride thin film—such as temperature, gas flows of SiH4, Si2H6, NH3, H2 and N2, N2O, CO2, chamber pressure, and plasma power—may be optimized to provide for a relatively high Si—H bond density with minimal light absorption at all wavelengths 300-1600 cm-1.

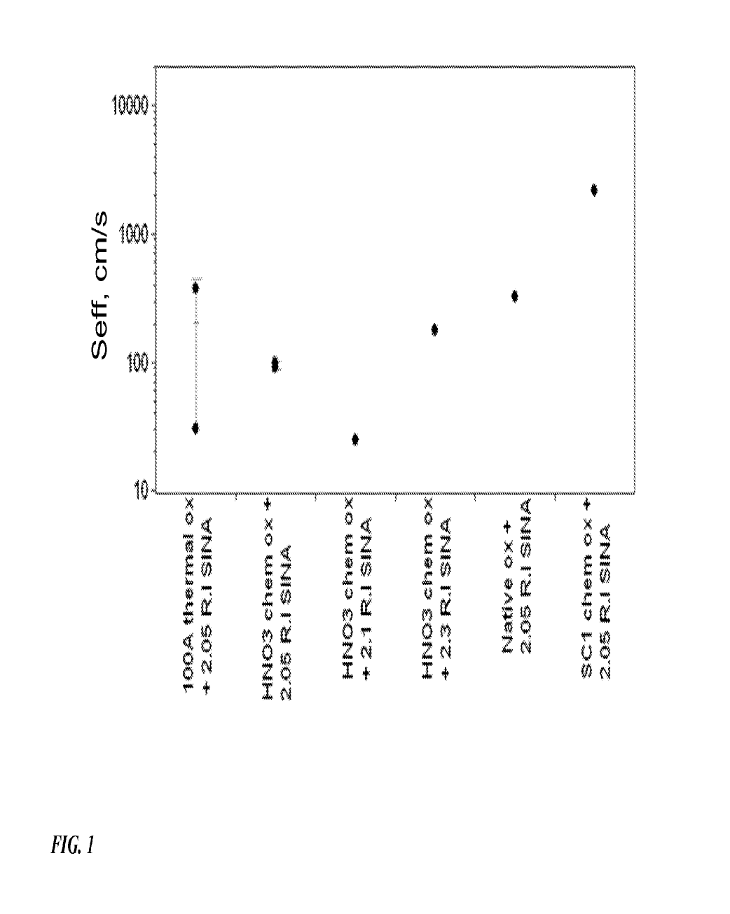

FIG. 1 is a graph presenting actual measured results as a comparison of surface passivation quality (Seff) with PECVD SiNx film refractive index (RI) on a dual layer stack with wet chemical oxide showing tuning deposition parameters of SiN at 400° C. Historically front (light receiving) side passivation is known to be improved with thermal oxide—which provides relatively low surface recombination velocities. Additionally, there have been extensive studies on the impact of silicon nitride deposition conditions and their impact on passivation. However, by utilizing the disclosed methods of dual layer passivation with anneal, the surface passivation improves quality dramatically—as shown by the measured results depicted in FIG. 1—and performs better than or equal to the performance of a dual layer stack of thermal (higher temperature) oxide and silicon nitride passivated surface at 400° C. A significant advantage of the disclosed processes is that the higher temperatures required for thermal oxide processing are not required in the disclosed bi-layer methods—thus reducing and avoiding the disadvantages associated with performing high temperature processes on thin film substrates.

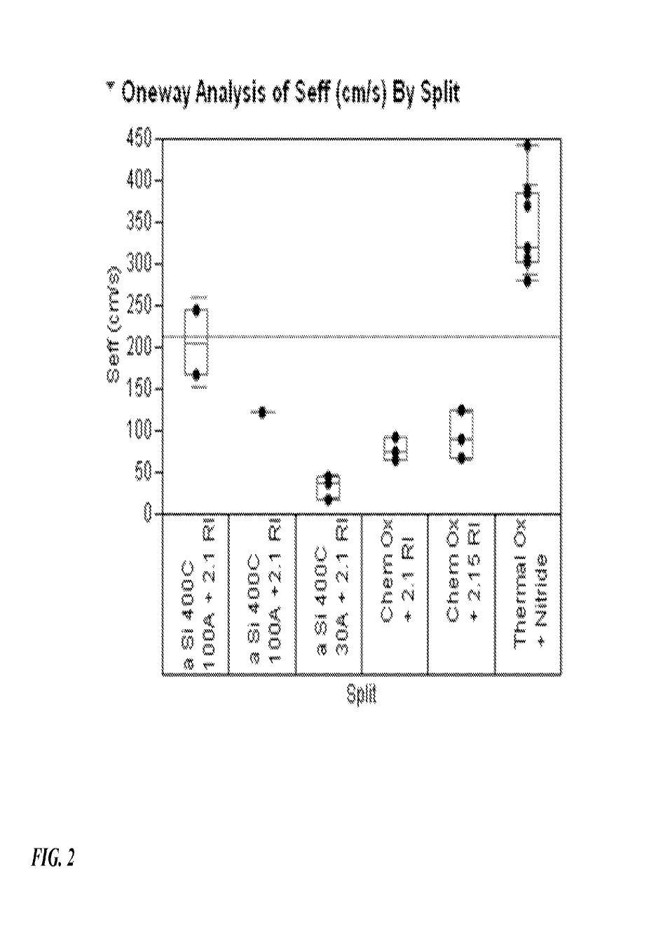

The disclosed subject matter comprises tuning the properties of deposited amorphous silicon and silicon nitride film to obtain optimal passivation. FIG. 2 is a graph presenting actual measured results showing a passivation quality comparison of 400° C. amorphous Si/SiN and chemical-oxide/400° C. SiN dual layer stack (bi-layer) with thermal (high-temp) oxide/SiN stack. Notice the equivalent or better performance of the amorphous-Si/SiN and chem-ox/SiN stack as a passivation layer as compared to the thermal (high-temp) oxide/SiN stack. The results depicted in the graph of FIG. 2—the measured interaction of deposition parameters and the impact of silicon nitride refractive index (RI) on passivation quality as measured by photo conductance decay—show that the RI between 2.0-2.3 works the best for passivation in dual layer passivation at a temperature of 400° C. when wet chemical oxide is used as one of the passivation layers.

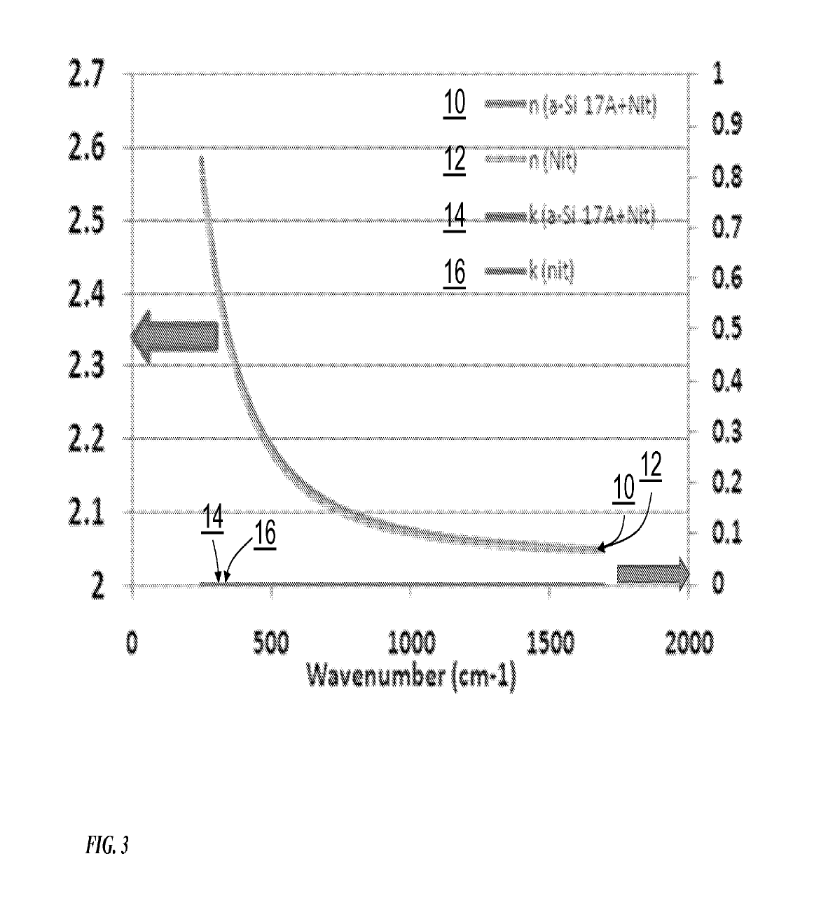

In the case of passivation bi-layer utilizing amorphous silicon as the first layer, deposition conditions and film thickness also impact passivation quality. FIG. 3 is a graph presenting actual measured results showing optical parameters i.e. refractive index(n) and extinction coefficient (k) vs wavelength for dual layer stack vs single layer SiN showing matched parameters with thin amorphous Si layer. As shown by the graph in FIG. 3, a thickness between 1-10 nm provides the best passivation without degradation in light absorption due to the presence of amorphous silicon layer. FIG. 3 also shows no change in extinction coefficient of the dual layer passivation stack with the presence of the thin amorphous silicon layer.

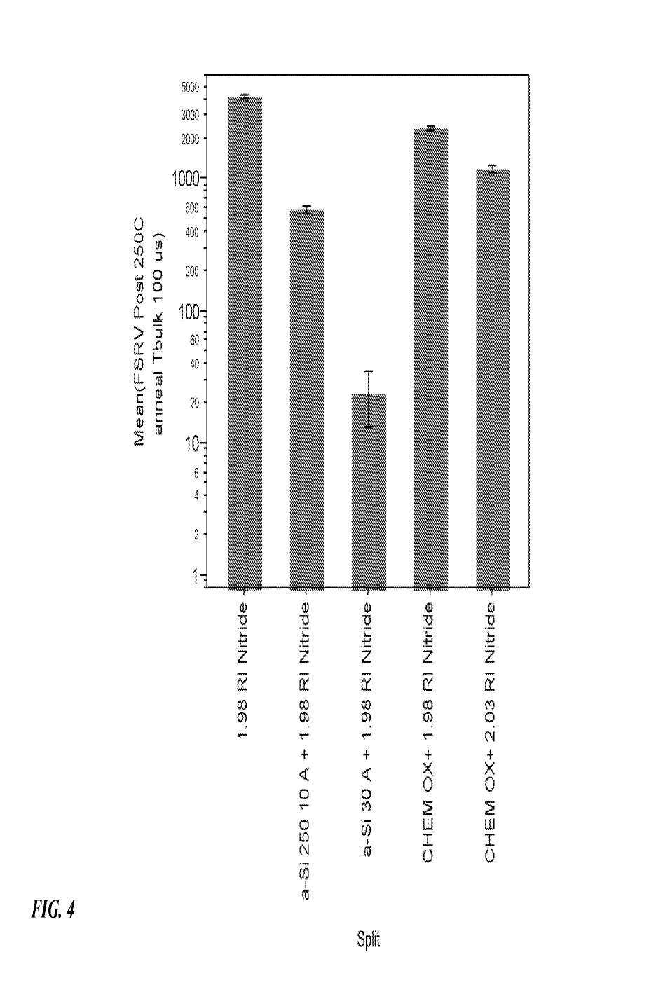

FIG. 4 is a graph presenting actual measured results showing passivation performance at 250° C. of dual layer stack (a-Si 10 A and 30 A/SiN and chem-ox/SiN)—note the 30 A a-Si/SiN stack achieves better performance. In yet another embodiment, superior surface passivation is achieved at very low deposition temperatures 150° C. using hydrogenated amorphous silicon thin film (such as a-Si, a-SiOC or a-SiON) and silicon nitride dual layer passivation with post deposition anneal at temperatures that are the same as deposition temperature. Using this low temperature passivation scheme, the thin amorphous silicon layer (1-10 nm) is deposited on the cleaned silicon substrate at a temperature ≦150° C., as described previously, using SiH4 with or without H2 followed by silicon nitride deposition at 150° C. followed by anneal at the same temperature of deposition for 1-120 minutes in N2 or FGA. As shown by the graph in FIG. 4, this method provides the same level of passivation as that of films deposited and annealed at temperatures ≧250° C. For lower temperature passivation the silicon nitride deposition parameters should be tuned to get an RI between 1.85-2.2.

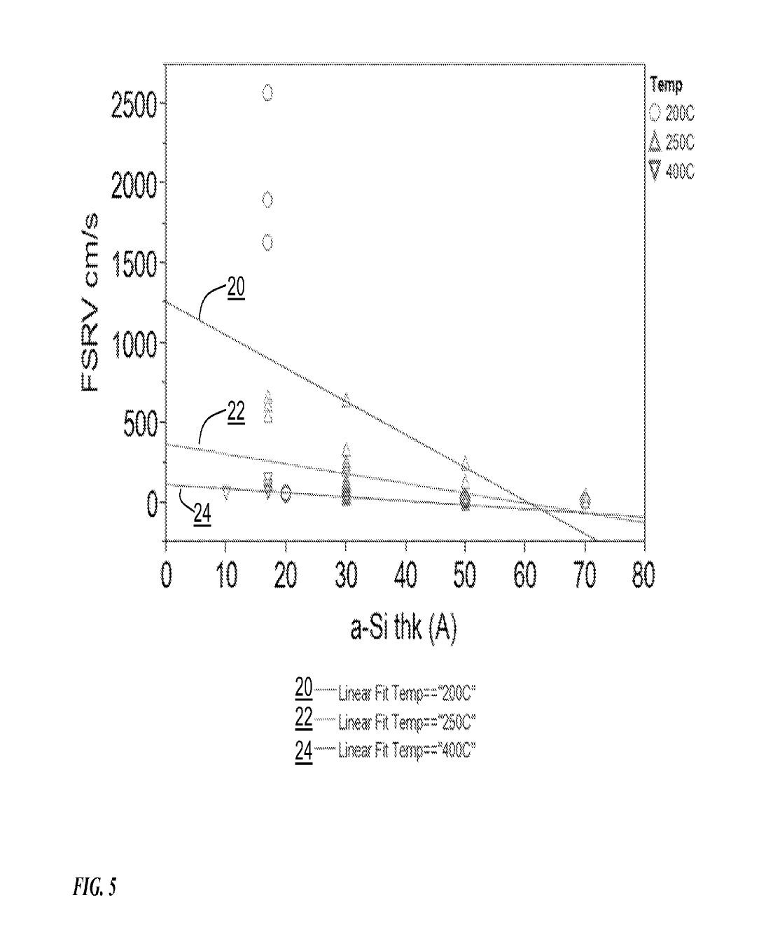

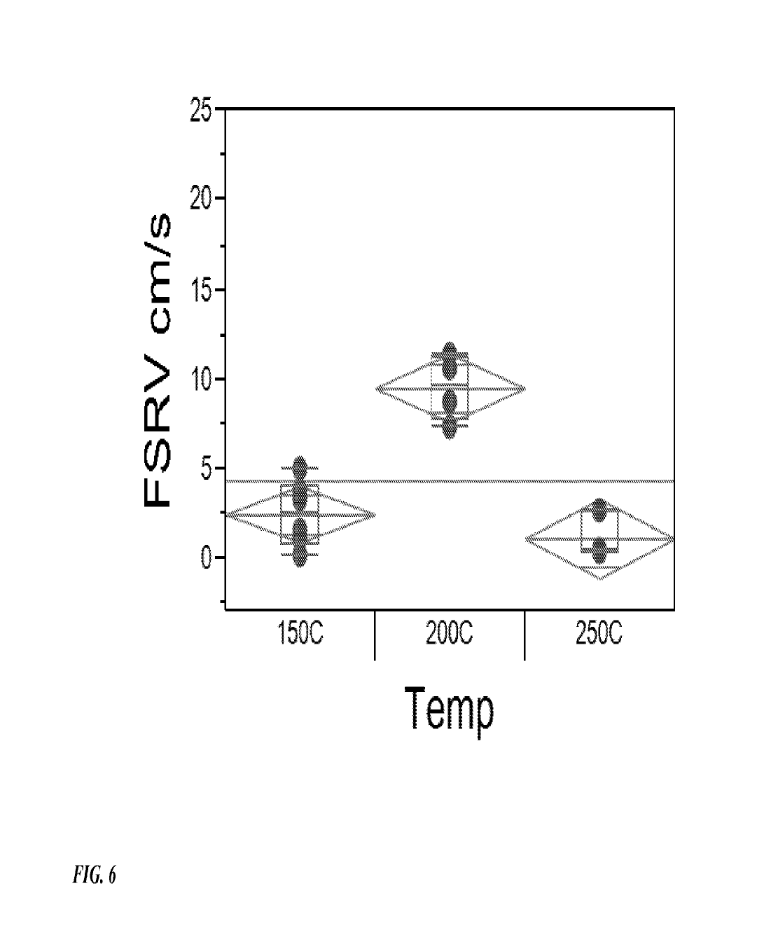

The disclosed methods further comprise tuning and adjusting the properties of deposited amorphous silicon and silicon nitride film to obtain optimal passivation at lower temperatures. FIG. 5 is a graph presenting actual measured results showing passivation (seff) vs amorphous Si layer thickness in an a-Si/SiN stack with varying processing temperatures showing equivalent performance at lower processing temperatures (such as 200° C.). As shown by the graph in FIG. 5, the measured impact of deposition parameters and the impact of amorphous silicon layer thickness shows that a thickness below 10 nm, and preferably between 3-10 nm, works best for passivation in dual layer passivation below 250° C. when amorphous silicon is used as one of the passivation layers. As shown by the graph in FIG. 6, understanding this relationship helped in reducing processing temperature further down to 150° C. FIG. 6 is a graph presenting actual measured results showing passivation (seff) vs temperature in a-Si/SiN stack with varying processing temperatures and showing equivalent performance at lower processing temperature at 150° C.

The methods provided give flexibility for silicon based device manufacturing as the passivation may be carried out in two steps or multiple steps if needed. For example, the formation of wet chemical oxide may be part of regular surface cleaning prior to deposition. Also, amorphous silicon deposition may be carried out in the same process step as that of silicon nitride or in the same chamber, adjacent chamber and with or without vacuum break.

While this disclosure describes reduced temperature surface passivation using dual-layer amorphous silicon and silicon nitride structures, additional embodiments also include structures which have bilayer or multilayer structures of amorphous silicon and/or bilayers or multilayer structures of silicon nitride (for example structures with different Si:N:H ratios in each layer). Moreover, for passivation layers which also serve as broadband Anti-Reflection Coating (ARC) layers in solar cells, the methods disclosed may also include additional materials deposited or formed on top of the passivation/ARC structures described.

In operation, the passivation methods described above are useful when the manufacturing methods require very low temperatures, for example <250° C., for passivation of the front/top (light receiving) side of the silicon substrate. The bi-layer methods disclosed provide good quality surface passivation with low surface recombination of minority carriers obtained at low temperatures of deposition followed by low temperature anneal. Further, the bi-layer passivation methods disclosed are particularly applicable for passivation of the front/top (light receiving) side of a thin film back contact back junction silicon solar cell because the low temperature processing is preferable for thin film substrates while maintaining the superior optical properties required for the light receiving surface of a back contact back junction solar cell. Additionally, the bi-passivation methods disclosed may include a thin, less than 80 microns, silicon (monocrystalline or multi-crystalline) absorber layer.

The passivation structures and methods herein provide a combination of excellent passivation with very-low surface recombination velocity (SRV), with SRV ≦50 cm/s (and in some instances with SRV 15 cm/s) while also achieving relatively stable passivation with negligible or minimal Light-Induced Degradation (LID) of the cell efficiency due to the passivation degradation under sunlight (such as extended exposure to ultraviolet or UV light). The structures and process methods disclosed are directly and particularly applicable for front-surface (also known as the sunnyside) passivation on back-contact, back-junction, crystalline silicon solar cells (also known as Interdigitated back-contact or IBC cells). These passivation structures and methods are also applicable to frontside and/or backside surface passivation in other types of crystalline (monocrystalline or multi-crystalline) Si solar cells, including but not limited to the heterojunction solar cells, bifacial solar cells, front-contact/back-junction cells, and other non-IBC back-contact cells.

Material structures and processing methods provided herein accomplish a combination of two key objectives:
High-performance (e.g., very low SRV 15 cm/s) surface passivation (on n-type and/or p-type crystalline silicon) with relatively low surface-state density (e.g., Dᵢₜ≦1×10¹¹ eV⁻¹ cm⁻²), in conjunction with an appropriate field-assisted passivation (fixed positive dielectric charges for n-type silicon or fixed negative dielectric charges for p-type silicon) to achieve high effective minority carrier lifetime (corresponding to high minority carrier diffusion length).
Excellent stability and resistance against Light-Induced Degradation (LID) of the passivation properties under extended sunlight and ultra-violet (UV) light exposure resulting in improved module performance reliability and reduced performance degradation in the field.

Further, in some instances the solutions provided may potentially eliminate the need for a doped Front-Surface Field (FSF) in silicon for LID resistance as sufficient LID resistance may be provided by the passivation itself.

As noted, high-quality (i.e., low surface recombination velocity) surface passivation is an important requirement to enable a high conversion efficiency for crystalline silicon solar cells. The quality of surface passivation may become increasingly critical requirement as the thickness of the silicon absorber layer is decreased (hence, the surface passivation quality may become more important than the bulk lifetime). For thin silicon less than about 100 micrometers, a permanent backplane support may be used for reliable handling and processing and permanent support. The backplane support may also add thermal processing complexity as backplane materials may be bound to limited temperature processing ranges. Typical processes for passivation of silicon solar cells use a process temperature that is above the operating limit of most polymeric backplane materials (e.g., prepreg) used to bond and support a very thin silicon absorber. For example, the thermal diffusion of phosphorus dopant into n-type silicon to form a front surface field (FSF) for enhanced passivation quality (and for reduced parasitic base resistance and reduced resistive losses) conventionally requires relatively high silicon thermal process temperatures in the range of about 850° C. to about 1100°—a range above the decomposition temperature of most organic and polymeric materials that may be used for low cost backplanes utilized for support of silicon. Innovative new processes are needed for high-quality low temperature (low thermal budget) passivation of very thin (e.g., sub-100 micron absorber thickness) silicon solar cells bonded to backplane support material sheets.

For reliable solar cell performance with stable conversion efficiency, the passivation also needs to be very stable under direct sunlight and in particular tolerant to ultraviolet radiation. Absorption of ultraviolet radiation into or its interaction with the surface passivation layer and the surface passivation layer interface on the solar cell absorber can severely degrade passivation (i.e., increase the effective surface recombination velocity of the passivation layer, resulting in reduced effective minority carrier lifetime). Solar module materials such as encapsulants and glass may be engineered to reflect or block ultraviolet radiation and reduce or eliminate damage to the solar cell, but the tradeoff is often a higher module cost and/or a lower module efficiency. Hence passivation layer materials on the cell that are very stable in direct ultraviolet radiation are highly desirable. This may be a particularly important consideration for the front-surface passivation in back-contact/back-junction solar cells.

Surface passivation structures and processes are provided for forming stable and reliable passivation on silicon crystalline solar cells, including but not limited to the back-contact/back-junction solar cells. Process temperatures for the described processes are low enough (e.g., approximately ≦300° C.) to be used with a silicon absorber bonded to an organic or polymeric backplane support (e.g., prepreg). For example, and as described above, CVD (e.g. PECVD, APCVD etc.), ALD, or other deposition methods for deposition of a dopant and/or top layer (e.g., dielectric, ARC, etc.) may be performed at temperatures less than 500° C. and more particularly less than 250° C. Additionally, in some instances and dependent on other considerations amorphous silicon may be processed at lower temperatures as compared to crystalline silicon.

In some instances, an additional anneal step may not be required as deposition methods themselves may provide thermal activation (particularly in the case of ALD). In other instances, after deposition of the passivation stack the substrate may be annealed at the same temperature as the temperature of deposition, although the annealing temperature may be higher (for example between 100-500° C., or more particularly 100-450° C.). Further, performing post anneal in a vacuum, in nitrogen or forming gas (N2, H2, NH3, or forming gas ambient such as N2+H2) may improve the passivation. For example, maintaining the anneal temperature between 100-450° C. for about 1-120 minutes helps preserve the optical properties of the passivation layer for its conducive use as an anti-reflective coating (ARC) and improves the surface passivation. However, importantly the process embodiments of the disclosed subject matter may or may not utilize post-deposition annealing in forming gas or nitrogen.

Selective laser surface anneal may also be utilized to thermally activate deposited layers (e.g., form a front surface field and/or anneal to improve passivation) while limiting anneal temperature to the cell frontside and decreasing the risk of overheating on the cell backside and backplane.

A stable surface passivation in crystalline silicon may be implemented by creating a more heavily doped (as compared to the background base doping) region (e.g., a front surface field and/or a doped dielectric layer) directly under the passivation layer on the silicon absorber surface. A doped first layer as compared to an undoped first layer may in some instances and dependent on other considerations provide increased passivation stability. A dopant precursor or a doped dielectric layer may used to form a front surface field within the silicon absorber (i.e. a dopant source) and/or a doped dielectric layer may be deposited on the silicon absorber (i.e. a passivation layer).

The dielectric layer may comprise, for example, intrinsic amorphous silicon (α-SixHyFz); intrinsic amorphous silicon oxide (α-SixOwHyFz); aluminum oxide (AlOx); hafnium oxide (HfOx); intrinsic amorphous silicon carbide (α-SixCwHyFz); intrinsic amorphous silicon nitride (α-SixNwHyFz); and/or intrinsic amorphous silicon with any combination of O and/or C and/or N. Dopants and/or dopant precursors may comprise, for example, phosphorous, arsenic, boron, gallium, and/or fluorine. Thus, a doped dielectric layer may comprise phosphorous doped (and in some instances also fluorine doped) aluminum oxide. A front surface field may be formed on and within (into) the cell absorber itself using the dielectric layers disclosed herein.

An ARC (anti reflection coating) layer, also referred to herein as an overlayer, is deposited on the front surface field and/or doped dielectric layer. For example, passivation and ARC materials include but are not limited to hydrogenated amorphous silicon (a-Si:H), silicon oxide (a-SiOx:H), silicon oxycarbide nitride (a-SiOxCyNz:H), aluminum oxide (AlxOy), and silicon nitride (a-SiNx:H). Plasma enhanced chemical vapor deposition (PECVD) or atomic layer deposition (ALD) may be used for overlayer deposition while maintaining the silicon at relatively low temperatures (e.g., ≦350° C.) during deposition.

For exemplary FSF embodiment, for an n-type silicon absorber (i.e., n-type base) with base phosphorus doping on the order of about 1×10¹⁵ to 1×10¹⁶ cm⁻³, a surface region with thickness less than approximately one micrometer and higher n-type phosphorus doping compared to the base doping level, for example greater than about 1×10¹⁷ cm⁻³, creates a built-in electric field under the silicon surface that can repel the positively charged minority hole carriers from the silicon surface (or the silicon/passivation layer interface). This front surface field (FSF) within the silicon may make the solar cell performance less sensitive to the passivation layers or changes (such as the surface states at the passivation layer/silicon interface) due to light damage or ultraviolet light damage in the passivation layers that are in contact on the silicon surface.

Importantly, the FSF embodiments provided may be used as a first layer in combination with an anti-reflection coating layer or in combination with a doped dielectric layer (e.g., fluorinated, phosphine, or otherwise doped) in combination an anti-reflection coating layer as disclosed herein.

The FSF layer may be formed by flowing precursor (e.g., phosphine, fluorine, or diborane) over the substrate or depositing a doped dielectric layer for example intrinsic amorphous silicon (α-SixHyFz); intrinsic amorphous silicon oxide (α-SixOwHyFz); aluminum oxide (AlOx); hafnium oxide (HfOx); intrinsic amorphous silicon carbide (α-SixCwHyFz); intrinsic amorphous silicon nitride (α-SixNwHyFz); and/or intrinsic amorphous silicon with any combination of O and/or C and/or N followed by thermal activation. Dopants may comprise, for example, phosphorous, arsenic, boron, gallium, and/or fluorine. Thus, a doped dielectric layer may comprise phosphorous doped (and in some instances also fluorine doped) aluminum oxide.

In one embodiment, an ultrathin surface field may be formed on the crystalline silicon by flowing a dopant containing gas or precursor on the silicon surface. Ultrathin (thickness range on the order of fractional or sub-mono-layer or about sub-mono-layer adsorbed—chemisorbed—layer up to a few monolayers or about several nm - - - ˜0.001 nm up to ˜1 nm) Front-Surface Field (FSF), for example formed in vacuum as a surface preparation process in a dopant +H2 gas prior to the deposition of the passivation (and anti-reflection-coating or ARC) layer(s).

For an n-type sunnyside FSF (for example an IBC solar cell using n-type base), the above-mentioned FSF process may use a mixture of PH3 in H2 at a low process pressure (e.g, mTorr to Torr range) in vacuum-integrated PECVD passivation equipment in order to incorporate a fraction of a monolayer up to about nearly a monolayer of substitional phosphorus on the atomically clean (and initially hydrogen-passivated) silicon surface. Alternatively, alternative n-type dopant sources such as AsH3 may be used (instead of PH3).

The atomic-layer FSF may be formed using either a non-plasma (such as a low-pressure atomic-layer deposition or ALD process) or a soft RF or microwave plasma process, in vacuum, and prior to the subsequent PECVD process for deposition of the passivation and ARC layer(s). The passivation and ARC layer(s) may be a single dielectric layer (such as hydrogenated silicon nitride) or a stack of amorphous silicon and silicon nitride (such as one of the embodiments provided herein).

Prior to processing the crystalline silicon, the surface is cleaned to remove surface contaminants such as native oxides (for instance, using a wet cleaning process with a last process step involving dilute HF etching of native oxide). Then, for an n-type silicon absorber, a phosphorus containing dopant gas such as phosphine (PH3) or a phosphorus precursor such as diethyl 1-propylphosphonate may be flowed onto the silicon surface (PH3 may be mixed with hydrogen). For a p-type silicon absorber, a boron containing dopant gas such diborane (B2H6) or a boron precursor such as allylboronic acid pinacol ester may be used. The decomposition of the gas or precursor may adsorb a sub-monolayer up to few monolayers of dopants onto and into (i.e. within) the silicon surface. The decomposition of the dopant gas or precursor may be enhanced by creating a gentle plasma with the dopant source above the silicon surface.

The dopant may also be directly ion implanted into the silicon surface, for instance, using a low-energy (<0.2 keV) plasma immersion ion implantation. The temperature of the silicon surface may be optimized to enhance the decomposition of the gas or precursor while keeping the temperature of the backplane support material below its decomposition temperature.

A surface dopant layer with thickness of a few atomic layers also may be formed by alternating exposures of the surface to the dopant source and a reducing agent gas such as hydrogen. This type of processing is often called atomic layer deposition (ALD).

After decomposition of the dopant on the silicon surface, thin film passivation layers may be deposited on top of the dopant layer. Passivation materials on crystalline silicon are hydrogenated amorphous silicon (a-Si:H), silicon oxide (a-SiOx:H), silicon oxycarbide nitride (a-SiOxCyNz:H), aluminum oxide (AlxOy), and silicon nitride (a-SiNx:H). Plasma enhanced chemical vapor deposition (PECVD) or atomic layer deposition (ALD) may be used to maintain the silicon at relatively low temperatures (e.g., ≦350° C.) during deposition.

For a sub-monolayer up to about one monolayer of adsorbed dopant, the relatively low thermal budget of the subsequent PECVD passivation process may be sufficient to fully activate the ultrathin atomic-layer or sub-atomic-layer FSF. For a thicker FSF layer (on the order of a few to many atomic layers), the dopant may be subsequently diffused from the dopant layer into the silicon and activated in the silicon surface by using a laser to anneal the dopant layer and silicon surface. A laser anneal with very short pulses of energy onto the surface enables selective heating of the silicon surface while maintaining the backside silicon and backplane at relatively low temperatures (i.e., backside of the cell maintained less than ≦350° C.). Further, a low temperature anneal as outlined above provides comprehensive low temperature cell fabrication processing.

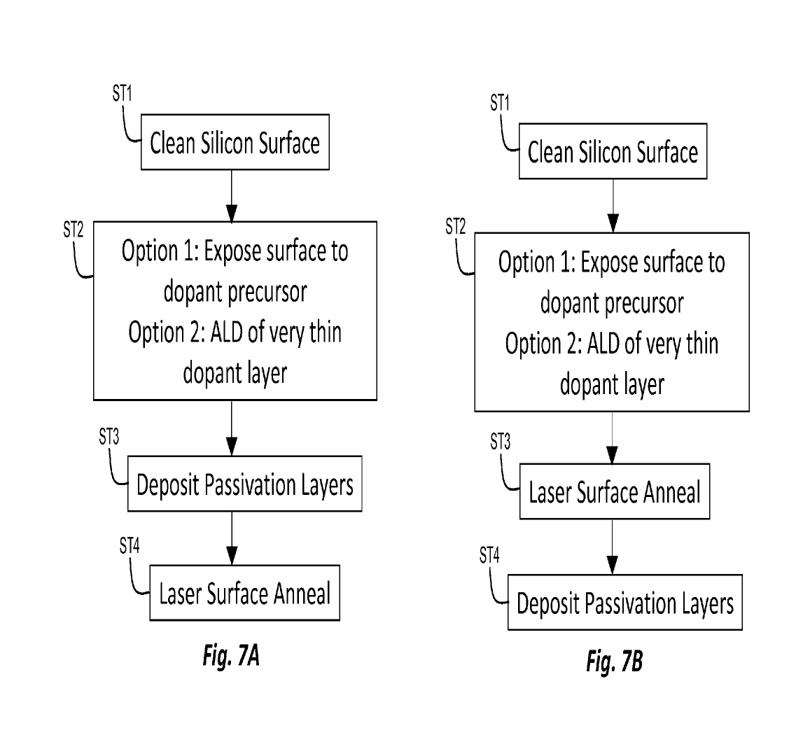

FIG. 7A is a high level process flow for low temperature stable silicon surface passivation comprising cleaning the crystalline silicon surface (ST1 of FIG. 7A), formation of a dopant layer on the surface by precursor exposure or ALD (ST2 of FIG. 7A), deposition of passivation layers (ST3 of FIG. 7A), and then laser surface anneal (ST4 of FIG. 7A).

Alternatively laser anneal of the dopant layer may be performed before deposition of thin film passivation layers. FIG. 7B is a high level process flow for low temperature stable silicon surface passivation comprising includes cleaning the crystalline silicon surface (ST1 of FIG. 7B), formation of a dopant layer on the surface by precursor exposure or ALD (ST2 of FIG. 7B), laser anneal of the dopant layer (ST3 of FIG. 7B), and then deposition of the passivation layers (ST4 of FIG. 7B). Note the flow of FIG. 7B is consistent with that of FIG. 7A except that steps ST3 and ST4 are performed in opposite order.

For passivation on n-type silicon the dopant layer (e.g., ALD layer) may contain an n-type dopant such as phosphorous or arsenic. For passivation on p-type silicon the dopant layer (e.g., ALD layer) may contain a p-type dopant such as boron or gallium.

Additionally, for example, assume a solar cell using n-type silicon (e.g., a back-contact/back-junction IBC solar cell), a bi-layer passivation and an anti-reflection coating (ARC) stack comprising two different material layers embodiment may be formed, as described below:
An ultrathin (i.e. one atomic layer—up to 10 nm and in some instances having a thickness in the range of sub-atomic layer) doped dielectric layer. The dielectric layer may comprise, for example, intrinsic amorphous silicon (α-SixHyFz); intrinsic amorphous silicon oxide (α-SixOwHyFz); aluminum oxide (AlOx); hafnium oxide (HfOx); intrinsic amorphous silicon carbide (α-SixCwHyFz); intrinsic amorphous silicon nitride (α-SixNwHyFz); and/or intrinsic amorphous silicon with any combination of O and/or C and/or N; or a micro-crystalline silicon. Dopants may comprise, for example, phosphorous, arsenic, boron, gallium, and/or fluorine. Thus, a doped dielectric layer may comprise phosphorous doped (and in some instances also fluorine doped) aluminum oxide. More particularly, this ultrathin dielectric layer (e.g. having a thickness in the range of about 2 to 7 nm) may be under-layer of intrinsic (undoped) hydrogenated amorphous silicon with a small controlled amount of fluorine incorporation (with fluorine atomic % smaller than the hydrogen atomic %), α-SixHyFz, directly deposited on the atomically clean n-type crystalline silicon cell absorber surface frontside (sunnyside). Controlled incorporation of fluorine atoms into the hydrogenated amorphous silicon (α-SixHyFz) layer as well as at the α-SixHyFz/crystalline silicon interface results in a more reliable, stable, and LID-resistant (UV-resistant) passivation layer (by formation of Si—F bonds besides Si—H bonds in the α-SixHyFz layer) which is more resistant against interface degradation (hence much reduced rate of surface state density or Dᵢₜ degradation under sunlight and UV light).
An overlayer of an anti-reflection coating (ARC) layer, e.g. a hydrogenated silicon nitride (SixNyHz) layer, in the thickness range of about 50 nm to 100 nm (and more particularly in the thickness range of about 60 nm to 80 nm). This overlayer SixNyHz has two key functions: (i) serves as an optical ARC layer to minimize optical reflection losses of sunlight from the solar cell (hence, maximizing sunlight transmission), and (ii) provides field-assisted improved passivation effect (for reduced SRV) due to the fixed positive charges formed in the SixNyHz layer (e.g., positive Qf on the order of 1×10¹¹ to 5×10¹³ cm⁻²). For example, the SixNyHz layer may be one of the following: (i) a single layer of SixNyHz with stoichiometric silicon—nitrogen content (refractive index ˜2.0), or (ii) a single layer of silicon-rich SixNyHz (refractive index >2.0 to ˜2.3)—this option also provides benefits in terms of suppression of potential-induced degradation (PID), or (iii) a bi-layer of SixNyHz comprising an under-layer of silicon-rich SixNyHz (refractive index >2.0 to ˜2.3) layer (for PID suppression and/or enhanced positive fixed charge density), and an over-layer of stoichiometric or near-stociometric layer of SixNyHz (e.g., with refractive index on the order of about 1.9 to 2.1). Optionally but not necessarily, the silicon nitride layer(s) may also be slightly fluorinated (i.e., SixNyHzFw).

Alternatively the surface passivation layers or sub-surfaces of the crystalline silicon may be fluorinated (fluorine doped) by exposure to a fluorine-containing gas or precursor. The fluorination process may occur before or after deposition of passivation thin films. A plasma or ion implantation also may assist the fluorination process. The temperature of the silicon and thin films during doping processing may be optimized to enhance the fluorination while keeping the temperature of the backplane support material below its decomposition temperature.

Structures and methods with a doped dielectric layer—e.g. a doped dielectric layer having controlled fluorination of (fluorine incorporation in) the passivation layer/crystalline silicon interface and the layer in direct contact with the crystalline silicon absorber—(defined as an Underlayer or Layer 1), with the Underlayer or Layer 1 including one or a combination of the following, for example: intrinsic (undoped) amorphous silicon (α-SixHyFz); intrinsic (undoped) amorphous silicon oxide (α-SixOwHyFz); intrinsic (undoped) amorphous silicon carbide (α-SixCwHyFz); intrinsic (undoped) amorphous silicon nitride (α-SixNwHyFz); and/or intrinsic (undoped) amorphous silicon with any combination of O and/or C and/or N.

Additional passivation structures comprising the above-mentioned Underlayer or Layer 1, further comprising an Overlayer or Layer 2 deposited after and positioned over the Underlayer or Layer 1, with Layer 2 serving one or a combination of the Anti-Reflection Coating (ARC) and field-assisted passivation functions, Layer 2 comprising one of the following: hydrogenated silicon nitride (SixNyHz)—with (near) stoichiometric refractive index (˜about 1.9 to 2.0), with or without controlled fluorination; silicon-rich hydrogenated silicon nitride (SixNyHz)—with higher than stoichiometric refractive index (about >2.0 to 2.3), with or without controlled fluorination; and/or hydrogenated silicon nitride (SixNyHz) with graded composition (at least two different refractive indices, e.g., Si-rich followed by stoichiometric nitride, with or without controlled fluorination.

Layer 1 and Layer 2 may be formed by Plasma-Enhanced Chemical-Vapor Deposition (PECVD). Fluorination during the PECVD process may be achieved by adding a suitable fluorine-containing gas such as SiF4 or SiHF3 or SiH2F2 or another suitable gas (e.g., CxFy).

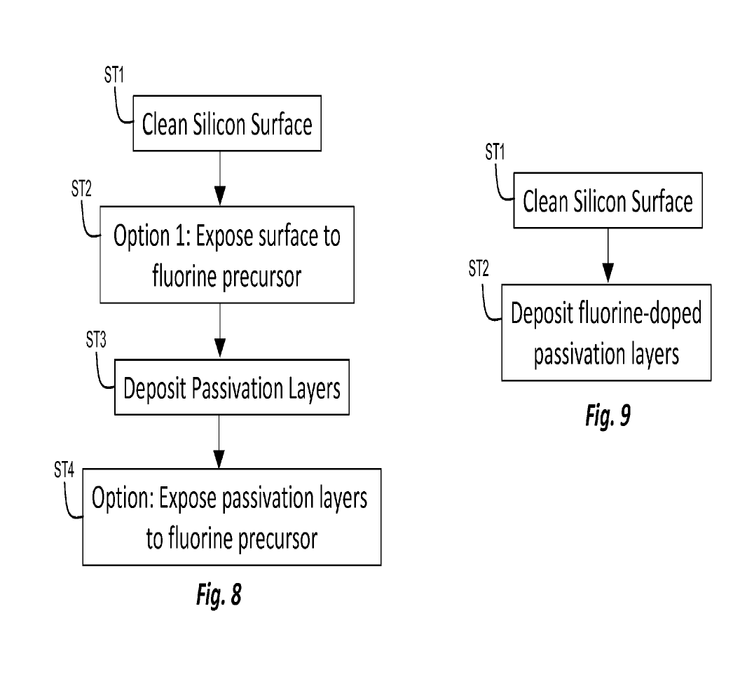

FIG. 8 is a high level process flow for low temperature stable silicon surface passivation comprising cleaning the crystalline silicon surface (ST1 of FIG. 8), an optional exposure of the surface to a fluorine precursor (ST2 of FIG. 8), deposition of the passivation layers (ST3 of FIG. 8), and then another optional exposure to a fluorine precursor (ST4 of FIG. 8).

Another embodiment to create a stable passivation layer is to directly deposit a fluorine doped (or fluorinated) passivation layer, such as hydrogenated amorphous silicon (a-Si:H) thin film or dielectric silicon oxycarbide nitride (a-SiOxCyNz:H) thin film, onto the crystalline silicon surface. A fluorine doping content of less than 10 percent in the thin film may improve stability under light exposure if for example stronger fluorine-silicon bonds are created compared to weaker hydrogen-silicon bonds. The thin film may be deposited by plasma enhanced chemical vapor deposition (PECVD), for example. The thin film may be fluorine doped by co-flowing a fluorine containing precursor such as fluorine gas (F2), silicon tetrafluoride (SiF4), fluorocarbon (CF4, C2F6, C3F6), nitrogen trifluoride (NF3), or silicon hexafluoride (SF6) during a deposition process that includes flowing a silicon precursor such as silane (SiH4) or disilane (Si2H6). Additional gases such as hydrogen (H2), and phosphorus or boron containing dopant gases, also may be co-flowed during the thin film deposition process.

FIG. 9 is a high level process flow for low temperature stable silicon surface passivation comprising cleaning the crystalline silicon surface (ST1 of FIG. 9) and then deposition of the fluorine-doped passivation layers (ST2 of FIG. 9).

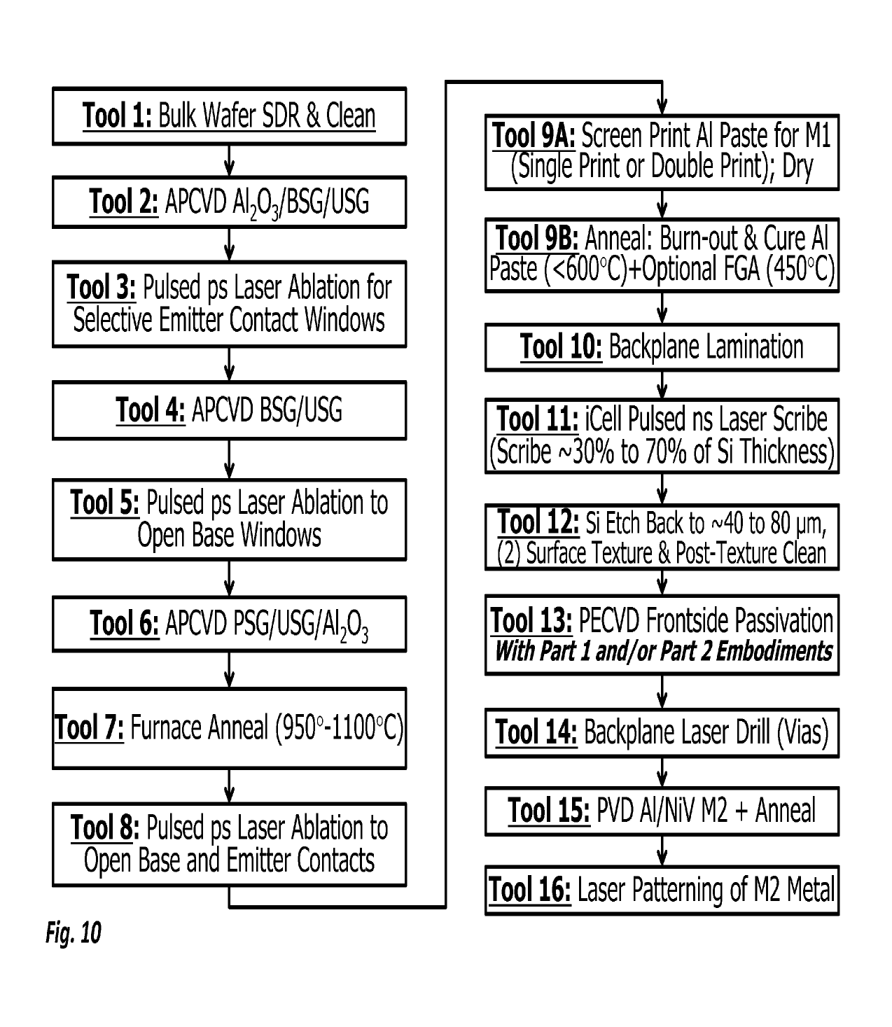

FIG. 10 is a representative process flow for forming a back contact back junction backplane attached solar cell in accordance with the disclosed subject matter. Passivation structures are deposited in Tool 13 Additional solar cell fabrication details may be found in U.S. patent Ser. No. 14/179,526 filed Feb. 2, 2014 which is hereby incorporated by reference in its entirety.

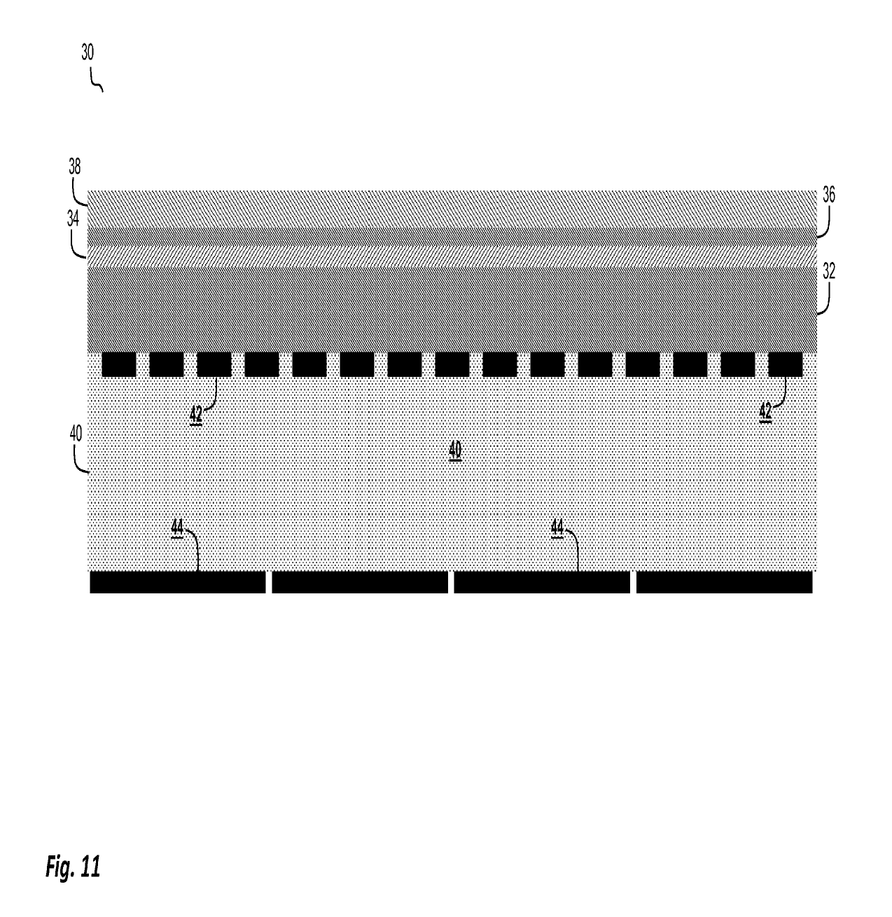

FIG. 11 is a cross-sectional diagram of a representative back contact back junction solar cell in accordance with one embodiment of the disclosed subject matter, for example a cell which may have been fabricated according to process flow of FIG. 10. The frontside or sunnyside of back contact back junction solar cell 30 comprises a passivation and antireflection coating—e.g. comprising an amorphous silicon and silicon nitride stack as provided herein—on the frontside of cell absorber 32 (e.g., a thin semiconductor such as crystalline silicon formed through thicker wafer etch-back). FSF 34 (e.g., n-type FSF for an n-type silicon absorber) is formed within the frontside of cell absorber 32. Doped dielectric layer 36 (e.g. fluorinated hydrogenated amorphous silicon, silicon oxide, or silicon carbide) is formed on FSF 34. ARC layer 38 (e.g., single layer or multi-layer ARC such as SixNyHz, and/or SixNyHz) also referred to as an overlayer herein, is formed on doped dielectric layer 36.

The backside of cell absorber 32 comprises on-cell interdigitated first metallization (M1) pattern 42 (e.g., busbarless thin Al metal fingers), backplane 40 (e.g., a laminated flexible polymeric sheet such as prepreg), and a second metallization (M2) pattern 44 (e.g., a PVD deposited patterned metal orthogonal to M1 and formed of aluminum and/or copper having a thickness in the range of approximately 1 to 5 microns).

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A passivation structure on a surface of a crystalline silicon substrate, comprising:
a doped dielectric layer serving as a surface passivation layer and also as a dopant source forming a doped front surface field with a thickness less than about one micrometer within said surface of said crystalline silicon substrate; and
a plasma-deposited hydrogen-containing silicon nitride layer on said doped dielectric layer.

2. The passivation structure of claim 1, wherein said doped dielectric layer is amorphous silicon.

3. The passivation structure of claim 1, wherein said doped dielectric layer is micro-crystalline silicon.

4. The passivation structure of claim 1, wherein said doped dielectric layer is phosphorus doped.

5. The passivation structure of claim 1, wherein said crystalline silicon substrate comprises monocrystalline silicon.

6. The passivation structure of claim 1, wherein said crystalline silicon substrate comprises multi-crystalline silicon.

7. The passivation structure of claim 1, wherein said doped dielectric layer is doped amorphous silicon oxide.

8. The passivation structure of claim 1, wherein said doped dielectric layer is doped amorphous silicon carbide.

9. The passivation structure of claim 1, wherein said doped dielectric layer is doped amorphous silicon oxy-carbide.

10. The passivation structure of claim 1, wherein said crystalline silicon substrate has n-type doping.

11. The passivation structure of claim 1, wherein said doped dielectric layer is fluorine and phosphorus doped.

12. A crystalline silicon photovoltaic solar cell structure, comprising:
a surface passivation structure on a surface of an n-type crystalline silicon substrate;
a doped dielectric layer comprising an n-type dopant on said surface of said crystalline silicon substrate; and
a plasma-deposited hydrogen-containing silicon nitride layer on said doped dielectric layer.
